(19) United States
(12) Patent Application Publication
(10) Pub. No.: US 2007/0237897 A1
(43) Pub. Date: Oct. 11, 2007

(54) Device and method for coating a microstructured and/or nanostructured structural substrate

(76) Inventor: Erich Thallner, St. Florian (AT)

Correspondence Address: KUSNER & JAFFE;HIGHLAND PLACE SUITE 310, 6151 WILSON MILLS ROAD, HIGHLAND HEIGHTS, OH, 44143, US

(21) Appl. No.: 11/390,822

(22) Filed: Mar. 28, 2006

(51) Int. Cl. B05C 5/00; C23C 14/00; B05D 3/00

(52) U.S. Cl. 427/294; 118/50; 118/52; 118/320; 118/689; 118/300; 427/299

(57) ABSTRACT

The present invention relates to a device (1) and a method for coating a microstructured and/or nanostructured structural substrate (8). According to the present invention, the coating is performed in a vacuum chamber (3). The pressure level in the vacuum chamber (3) is elevated during or after the charging of the vacuum chamber (3) with coating substance.

The present invention relates to a device and a method for coating a microstructured and/or nanostructured structural substrate.

MEMS (micro electromechanical systems), MOEMS (microoptoelectromechanical systems), and NEMS (nanoelectromechanical systems) are a combination of mechanical and optical elements, sensors, actuators, and electronic circuits on a structural substrate. Furthermore, MEMS and NEMS may contain optical, chemical, and/or biological components. To manufacture MEMS and NEMS, it is usually necessary to provide the surface of the structural substrate, in particular a wafer, preferably made of semiconductor materials and/or moldable plastics, with a coating. Photoresist is usually used for this purpose, in order to transfer lithographic structures in a further method step.

Coating microstructured and/or nanostructured structural substrates of this type has been shown to be difficult. In contrast to the semiconductor industry, where wafers are used having a comparatively even surface are used, the microstructured and/or nanostructured structur substrates of the MEMS/MOEMS and NEMS are comparatively thickly structural substrates. These deep structures are generated through wet or dry etching, embossing, or molding, and may have greatly varying shapes and greatly varying depths and flank formations. The structures of the structural substrate frequently have steep flanks and often even perpendicular side walls. Currently, it is typical that depressions implemented pits and/or holes having a depth of approximately 300 μm and a width or a diameter of the upper opening of approximately 100 μm and an angle of inclination of the side walls of up to 70° are lacquered uniformly. The methods known from the semiconductor industry for surface coating, such as spin lacquering, application of photoresist films, or immersion lacquering, are not suitable, since the coating substance may not penetrate as far as the bottom of the depressions. Currently, it is typical to coat the structural substrate by the spraying method. For this purpose, a fine mist of coating substance mist is applied under standard atmospheric pressure to the surface of the structural substrate using an spray nozzle, the spray mist being deflected using air/oxygen or nitrogen (N₂). The problem frequently arises in this case that the coating substance droplets close the narrow openings of the depressions because of surface tension and do not wet all of the side walls and the floor of the depressions. Furthermore, applying the spray mist through electrostatic charging, similarly to the powder coating method, to the structural substrate at standard pressure atmosphere is known. However, the high electrical voltage required in this case may destroy the sensitive structures and/or circuits of the structural substrate.

The present invention is based on the object of suggesting a device and a method for coating a microstructured and/or nanostructured structural substrate, using which a uniform coating of the structured surface of the structural substrate with a coating substance is possible.

This object is achieved according to the device by the features of claim 1 and according to the method by the features of claim 9.

Advantageous developments of the present invention are specified in the subclaims.

The present invention is based on the idea of situating the structural substrate on a carrier unit in a vacuum chamber. The coating substance is introduced into the vacuum chamber before and/or while and/or after the chamber is evacuated. By applying a partial vacuum to the vacuum chamber, the air is suctioned off of the surface structure, i.e., out of the depressions of the structural substrate. The pressure level in the vacuum chamber is increased, preferably suddenly, even during and/or after the introduction of the coating substance into the vacuum chamber. In this way, the coating substance is conveyed/drawn into the depressions of the structural substrate, through which even very deep and narrow depressions are coated uniformly. Photoresist is preferably used as the coating substance. However, it is also possible to coat the structural substrate with other coating substances, such as surface activation agents, solvents, adhesion promoters, or other chemicals. Treating or coating the structural substrate multiple times in sequence, preferably using different coating substances, is within the scope of the present invention.

There are various possibilities for introducing the coating substance into the vacuum chamber. According to an especially simple variation, the coating substance is introduced into the vacuum chamber in the liquid state through an inlet line. However, misting the coating substance, for example, within the vacuum chamber, is more advantageous for achieving a uniform coating. For this purpose, spray nozzles, atomizer nozzles, and/or ultrasonic atomizers may be used. The finer the coating substance mist, the more uniform the resulting coating.

It has been shown to be advantageous to heat the structural substrate before elevating the pressure level in the vacuum chamber, particularly with the aid of heating elements of the carrier unit.

Optimum results are achieved if the structural substrate is cooled down again before and/or while the coating substance is introduced, particularly using cooling elements of the carrier unit. In this way, the condensation of coating substance mist in the depressions of the structural substrate is supported. Different temperature profiles and curves may be implemented with the aid of the heating and/or cooling elements, through which the coating result may be influenced for different structural substrates or coating substances.

Additionally or alternatively, it is conceivable to set the structural substrate in rotation, preferably using the carrier unit, while or after coating substance is introduced, in order to ensure optimum distribution of the coating substance on the surface of the structural substrate.

According to a preferred embodiment, the pressure elevation after the evacuation of the vacuum chamber is performed simultaneously with the introduction of coating substance and/or due to the introduction of coating substance.

According to the preferred embodiment, in addition to the vacuum chamber, a misting chamber is provided, which is connected via at least one connection line to the vacuum chamber. Misting means are provided within the misting chamber, particularly at least one nozzle and/or other suitable atomizer devices, for misting the coating substance. With the aid of the misting means, the coating substance is misted in the misting chamber. The pressure level in the misting chamber is higher in this case than the pressure level of the evacuated vacuum chamber. Even during or after the misting process in the misting chamber, the at least one connection line between misting chamber and vacuum chamber is opened, through which the coating substance mist flows suddenly at excess pressure from the misting chamber into the vacuum chamber, through which in turn the coating substance mist is conveyed/drawn into the depressions of the structural substrate and adheres uniformly to the side walls and the floor.

Optimum results are achieved if the coating substance or the coating substance mist is heated within the misting chamber before being introduced into the vacuum chamber.

Preferably, the at least one connection line is only opened after a desired coating substance concentration exists in the misting chamber. It is conceivable to monitor the coating substance concentration in the misting chamber, preferably through optical or chemical sensors. According to a simple embodiment, however, the misting chamber may be charged with coating substance over a predetermined time span before the connection to the vacuum chamber is produced.

In a development, the misting chamber is implemented having a changeable volume. The misting chamber preferably has a floor plate which is connected via a folded bellows to the remaining misting chamber. In this way, it is possible to influence the concentration of the coating substance mist within the misting chamber and influence the pressure level within the misting chamber via the change of the volume of the misting chamber.

The misting chamber advantageously also has a drain to be able to drain off excess coating substance.

It is conceivable to perform multiple coating procedures in sequence, particularly using different coating substances.

Further advantages and expedient embodiments may be inferred from the further claims, the description of the figures, and the drawing.

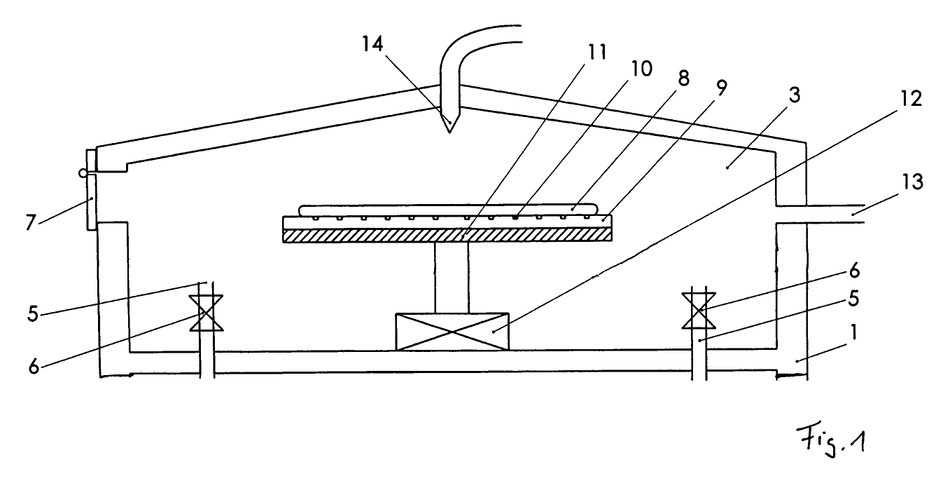

FIG. 1 shows a first exemplary embodiment of a device for coating a microstructured and/or nanostructured structural substrate, in which the coating substance is misted directly in a vacuum chamber and

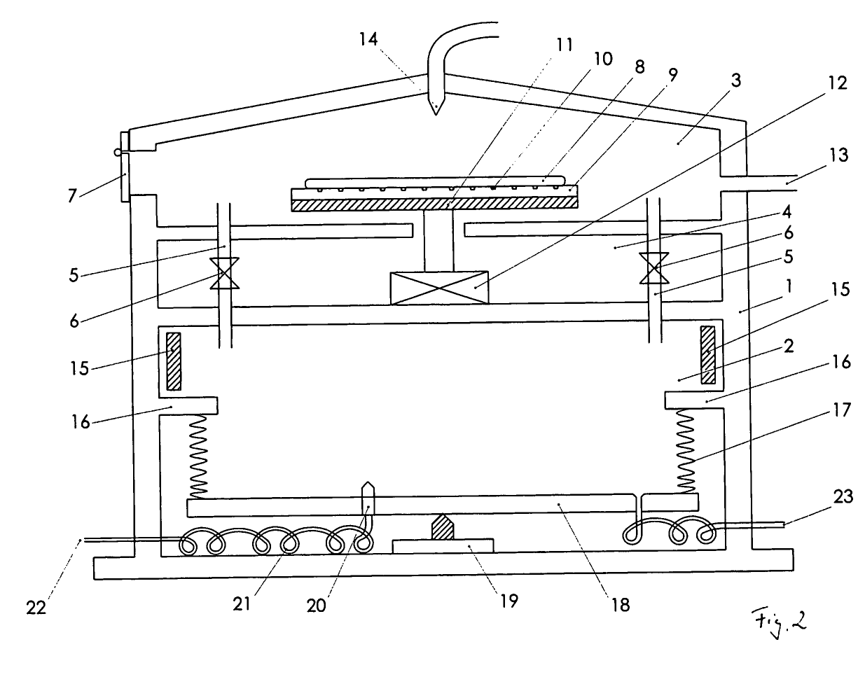

FIG. 2 shows a second exemplary embodiment of .a device according to the present invention having a misting chamber which is connected via closable connection lines to the vacuum chamber.

Identical components and components having identical function are provided with identical reference numbers in the figures.

FIG. 1 shows a device 1 for coating a microstructured and/or nanostructured structural substrate 8, a silicon wafer here. The structural substrate 8 has structuring having depressions on its surface pointing upward in the plane of the drawing, the depressions having a depth of approximately 100 μm to approximately 400 μm for MEMS. The width or the diameter of the upper openings of these depressions is in the range of 200 μm to 100 μm or less for MEMS. Therefore, in at least some of the depressions, the opening is dimensioned significantly smaller than its depth. Using the device 1 it is possible to coat the surface structure of the structural substrate 8 uniformly, particularly inside the depressions. For NEMS, the depressions have a width of 20 nm and a depth of 40 nm, for example.

The structural substrate 8 is fixed on a carrier unit 9 (chuck) in a vacuum chamber 3. Vacuum grooves 10 are provided for fixing the structural substrate 8 on the carrier unit 9. By applying a vacuum to the vacuum grooves 10, the bottom side of the structural substrate 8 is suctioned in the direction of the carrier unit 9. A closable flap 7 is provided for charging the vacuum chamber 9 with the structural substrate 8.

The carrier unit 9 has a combined heating-cooling element 11 in order to heat and cool the carrier unit 9 and therefore the structural substrate 8. With the aid of the combined heating-cooling element 11, greatly varying temperature profiles and/or curves may be implemented.

The carrier unit 9 is rotatable using a motor 12 in the fixing plane of the structural substrate 8, through which a uniform distribution of coating substance may be achieved if it was not applied in atomized form.

A misting nozzle 14 is provided for charging the vacuum chamber 3 with coating substance, any type of atomizer nozzle being able to be provided as a nozzle. This nozzle is situated directly above the surface of the structural substrate 8 to be coated.

To apply a partial vacuum to the vacuum chamber 3, i.e., to evacuate the vacuum chamber 3, the vacuum chamber 3 is connected via a vacuum line 13 to a vacuum system (not shown).

Furthermore, two spaced connection lines 5, each having a shutoff valve 6, are provided in the floor of the vacuum chamber 3. When shutoff valves 6 are opened, the connection lines 5 connect the vacuum chamber 3 to a higher pressure level than the pressure level of the evacuated vacuum chamber 3, preferably to the atmosphere or to an excess pressure pressure means store.

The structural substrate 8 is coated in the following way:

A structural substrate 8 is laid on the carrier element 9 using a robot via the opened flap 7. After the structural substrate 8 is fixed and vacuum is applied to the vacuum grooves 10, the vacuum chamber 3 is closed using the flap 7. The shutoff valves 6 are also closed at this time. The structural substrate 8 is now sprayed with coating substance by the misting nozzle 14, preferably a surface activation agent, a solvent, or photoresist. The coating substance used is process-specific depending on the surface composition of the structural substrate 8, and the structure of the pits or holes. In the further procedure, the carrier unit 9 may now be heated using the heating-cooling element 11. Even during the heating of the carrier unit 9 and therefore the structural substrate 8, the vacuum chamber 3 is evacuated via the vacuum line 13. After a predetermined time, the carrier unit 9 is cooled down using the heating-cooling element 11. Subsequently, the shutoff valves 6 are opened, through which excess pressure flows suddenly into the vacuum chamber 3 and pushes the misted coating substance into the depressions of the structural substrate 8 and thus ensures uniform coating.

It is also executable/possible to charge the vacuum chamber 3 with coating substance via nozzle 14 only after or even during the evacuation. The charging after the evacuation has the advantage that the coating substance is not suctioned through the vacuum line 13 during the charging. The shutoff valves 6 may be opened already during or after the charging with coating substance. Before opening the shutoff valves 6, process-specific temperature profiles may be run through, through which a change of the consistency and/or rheological properties of the coating substance is achieved.

In the exemplary embodiment shown in FIG. 2, a misting chamber 2 is provided in addition to the vacuum chamber 3. The construction of the vacuum chamber 3 having carrier unit 9 essentially corresponds to the construction shown in FIG. 1. In this embodiment, the misting nozzle 14 shown in FIG. 2 may also be dispensed with, so that the charging with coating substance is performed exclusively via the misting chamber 2.

An intermediate wall is inserted between the floor of the vacuum chamber 3 and the structural substrate 8, so that an intermediate chamber 4 is formed, in which the motor 12 of the carrier unit 9 is situated. The pressure level of the intermediate chamber 4 corresponds to the pressure level of the vacuum chamber 3. The intermediate chamber 4 may also be operated at atmospheric pressure. The shaft of the motor 12 is then sealed in the transition area between vacuum chamber 3 and intermediate chamber 4.

In contrast to the exemplary embodiment in FIG. 1, the connection lines 5 having their shutoff valves 6 do not connect the vacuum chamber 3 to the environment, but rather to the misting chamber 2.

Heating elements 15 are located in the upper area of the misting chamber 2 in order to be able to heat the misting chamber 2. A peripheral step 16 is located below the heating elements 15, which extends radially inward into the misting chamber 2. A floor plate 18 of the misting chamber 2 is connected via a peripherally closed folded bellows 17 to the step 16. The volume of the misting chamber 2 may be reduced or enlarged via an actuator 19, the folded bellows 17 folding together or apart during the adjustment procedure. A spray nozzle 20 is situated in the floor plate 18 for charging the misting chamber 2 with coating substance. Coating substance, preferably photoresist, solvent, or other chemicals, may be supplied to the misting chamber via a flexible connection line 21 and an adapter 22. The spray nozzle 20 is used for atomizing the coating substance, through which the volume of the misting chamber 2 is fillable with coating substance mist.

Furthermore, an opening is provided inside the floor plate 18, which is connected to a flexible drain line 23. Via this, excess liquids, particularly coating substance which accumulates in the misting chamber 2, may be removed.

The coating of structural substrates 8 in the device 1 shown in FIG. 2 is performed in the following way:

A structural substrate 8 made of semiconductor substrate or molded plastic or glass substrate, here a wafer made of silicon, is laid on the carrier unit 9 via the flap 7 and fixed using the vacuum grooves 10. The structural substrate 8 may now optionally be sprayed with a chemical substance, preferably a coating substance, by the nozzle 14. Preferably, the structural substrate 8 is sprayed with a surface activation substance, a solvent, or photoresist. After the optional spraying procedure, the vacuum chamber 3 is evacuated. The structural substrate 8 is first heated using the heating-cooling element 11 and then cooled again, preferably before the vacuum chamber 3 is charged with coating substance. During or after this, the misting chamber 2, which is preferably heated via the heating elements 15, is filled with a coating substance mist by the spray nozzle 20. The pressure level within the misting chamber 2 preferably corresponds to atmospheric pressure, but is higher than the pressure level of the evacuated vacuum chamber 3 in any case. After a sufficient filling of the misting chamber 2 with coating substance, whose concentration is monitored via optical or chemical sensors (not shown), the valves 6 of the connection lines 5 are opened, through which the vacuum chamber 3 suddenly fills with coating substance mist while simultaneously being supplied with pressure. Through the sudden pressure increase, in particular from vacuum to atmospheric pressure, and possibly due to different temperature profiles and/or curves of the carrier unit 9, a uniform lining of approximately 300 μm deep and approximately 100 μm wide cavities, pits, or other topographic figures which have a small opening on top in comparison to their depth, with a homogeneous protective layer, preferably a photoresist layer, is obtained.

Depending on the surface composition of the structural substrate, via the variation of the dwell time in the evacuated vacuum chamber 3 and via the flooding profile (liquid or mist) and via different temperature profiles of the carrier unit 9 and any repetition of the evacuation and charging cycles, a precisely defined coating substance deposition on all vertical, deep geometric forms of the structural substrate 8 may be achieved. Equalization of the deposition is achieved through rotation of the carrier unit 9. Possible excess liquid may also be thrown off.

### LIST OF REFERENCE NUMBERS

1 device
2 misting chamber
3 vacuum chamber
4 intermediate chamber
5 connection lines
6 shutoff valves
7 flap
8 structural substrate
9 carrier unit
10 vacuum grooves
11 heating-cooling element
12 motor
13 vacuum line
14 (misting) nozzle
15 heating elements
16 step
17 folded bellows
18 floor plate
19 actuator
20 spray nozzle
21 flexible connection line
22 connection
23 flexible drain line

1. A device for coating a microstructured and/or nanostructured structural substrate (8), having a carrier unit (9) situated in a vacuum chamber (3) for the structural substrate (8) and having introduction means (14, 5) for introducing coating substance into the vacuum chamber (3) and having means (5, 6, 2) for changing the pressure level in the vacuum chamber (3).

2. The device according to claim 1,
characterized in that the introduction means (14) are implemented as an inlet line and/or spray nozzle and/or atomizer nozzle and/or ultrasonic atomizer.

3. The device according to claim 1,
characterized in that the carrier unit (9) has heating and/or cooling elements (11) for heating and/or cooling the structural substrate (8).

4. The device according to claim 1,
characterized in that the structural substrate (8) is rotatable using the carrier unit (9).

5. The device according to claim 1,
characterized in that: a misting chamber (2) having misting means (20) for misting the coating substance, which is connected via at least one connection line (5) having a shutoff valve (6) to the vacuum chamber (3), is provided as a combined introduction and pressure changing means.

6. The device according to claim 5,
characterized in that at least one heating element (15) is provided for heating the misting chamber (2).

7. The device according to one of claim 5,
characterized in that the misting chamber (2) is implemented as changeable in volume.

8. The device according to claims 5 to 7,
characterized in that at least one sensor is provided inside the misting chamber (2) for detecting the coating substance concentration.

9. A method for coating a microstructured and/or nanostructured structural substrate (8), particularly using a device (1) according to claim 1, having the following method steps:
charging a vacuum chamber (3) with a structural substrate (8);
evacuating the vacuum chamber (3);
introducing a coating substance into the vacuum chamber (3) before and/or while and/or after it is evacuated;
elevating the pressure in the vacuum chamber (3) while, and/or after the coating substance is introduced.

10. The method according to claim 9,
characterized in that the coating substance, particularly after the evacuation of the vacuum chamber (3), is introduced into the-vacuum chamber in liquid form and/or is misted in the vacuum chamber (3).

11. The method according to claim 9,
characterized in that the structural substrate (8) is heated in the vacuum chamber (3), preferably over a predetermined time span.

12. The method according to claims 9 to 11,
characterized in that the structural substrate (8) is cooled, preferably before the coating substance is introduced, particularly after heating the structural substrate (8).

13. The method according to claims 9 to 11,
characterized in that the coating substance is misted in a misting chamber (2), and the coating substance is introduced into the vacuum chamber (3) by opening at least one shutoff valve (6) and at least one connection line (5) between misting chamber (2) and vacuum chamber (3), preferably after reaching a desired coating substance concentration in the misting chamber (3).

14. The method according to claim 13,
characterized in that the pressure level in the misting chamber (2) before the shutoff valve (6) is opened is higher than the pressure level of the evacuated vacuum chamber (3), and the pressure level in the misting chamber (2) preferably corresponds to atmospheric pressure.

15. The method according to one of claim 13,
characterized in that the misting chamber (2) is heated before and/or while the coating substance is misted.

16. The method according to claim 9,
characterized in that structural substrate (8) made of semiconductor substrate or embossed or molded plastic material or glass substrate, preferably a wafer, having depressions, preferably pits or holes, having a depth of approximately 10 nm to approximately 400 μm, is used.

17. The method according to claim 16,
characterized in that the width or the diameter of the depressions is less than their depth.

18. The method according to claim 9,
characterized in that photoresist and/or surface activation agent and/or solvent and/or adhesion promoter is/are used as the coating substrate.

19. The method according to claim 9,
characterized in that the method steps after the charging of the vacuum chamber (3) with the structural substrate (8) are repeated multiple times, preferably using different coating substances.

20. A use of a device according to claims 1 to 7, for coating a microstructured and/or nanostructured structural substrate (8) with a coating substance.
